(19) United States
(12) Patent Application Publication
(10) Pub. No.: US 2009/0178705 A1
(43) Pub. Date: Jul. 16, 2009

(54) Multi-cores stack solar thermal electric generator

(75) Inventors: Anjun Jerry Jin, Palo Alto, CA (US); John P. Gotthold, Sunnyvale, CA (US)

Correspondence Address: Rutan & Tucker, LLP., 611 ANTON BLVD, SUITE 1400, COSTA MESA, CA, 92626, US

(73) Assignee: HODA GLOBE CORPORATION

(21) Appl. No.: 12/229,708

(22) Filed: Aug. 26, 2008

Related U.S. Application Data
(60) Provisional application No. 60/966,675, filed on Aug. 30, 2007.

(51) Int. Cl. H01L 31/042

(52) U.S. Cl. 136/246

(57) ABSTRACT

A solar electric generator is disclosed which utilizes the natural energy of sunlight and converts it directly into DC electricity by means of a solid state thermal electric generator (TEG) at high efficiency. The solar electric generator converts sunlight into electricity in two steps: 1) sunlight energy is converted into heat in a lower chamber that contains a broadband photon trapper known as the blackbody; 2) the heat is converted into electricity through the TEG in an upper chamber illustrated in the figures. The thermal electric conversion component is packaged from thermally cascading stack of multiple TEG cores. Each of the cores is composed of materials optimized to exhibit the thermal electric effect at progressively lower temperatures.

### RELATED APPLICATIONS

This application claims benefit of Provisional Application No. 60/966,675 filed Aug. 30, 2007.

### FIELD OF INVENTION

The present invention relates to the field of power generation using thermal electric devices, referred to as solar thermal electricity generators.

### BACKGROUND OF THE INVENTION

The evolution of the production of electrical energy included water wheels or water dam driven turbine electrical generators, steam engine driven electrical generators, internal combustion engine electrical generators, natural gas or steam driven turbine electrical generators, coal fired steam driven turbine electrical generators and atomic power plant steam driven turbine electrical generators. All these prior methods of electricity production caused large environmental disruptions, such as flooding behind dams or air and water pollution from fossil fuel or nuclear fuels.

Recent developments with decreased environmental impact include the solar cell which utilized semiconductor devices to convert solar energy to electricity, originally developed to provide solar power for space craft. This technology provided for a thermal-to-electrical conversion with no moving parts. Some of its limitations are that the conversion efficiency from solar energy to electricity is theoretically limited to twenty nine percent in solar cells based on silicon. As a result of considerable effort the conversion efficiency of the practical solar cell is currently about fifteen percent.

In the prior art, collected solar energy has primarily been converted to electricity by solar thermal mechanical means such as Solar power towers, Solar trough arrays, Gen sets, OTECs (Ocean thermal electric converters). All of these devices collected solar thermal energy, concentrated said energy onto a heat exchanger, which directly or indirectly raised the temperature of a working fluid. The working fluid was then cycled through a turbine or Sterling engine to rotate or linearly actuate a generator and produce electricity. These systems were typically less than thirty percent efficient.

The primary non mechanical solar electric generator has been the varied forms of solar voltaic cells, which utilize solar photonic energy to excite electrons and cause them to jump a semi conductor band gap to produce DC electric flow. After decades of research solar voltaic cells are still limited to between fifteen to twenty percent conversion efficiency. The best aerospace multi-layer cells are approaching forty percent. The limitation of current solar cell technology to wide spread use is the high cost of sufficient array area to produce a significant amount of electricity.

### DISCUSSION OF THE CURRENT INVENTION

The primary limitation of the primary existing silicon solar cells is the fact that they can only utilize a narrow part of the solar spectrum, approximately sixteen percent. The multilayer cells utilize typically three layers, each layer optimized to collect a different part of the solar spectrum. The twin drawbacks to this approach are that building the three layers is complex and the top layers interfere to some degree with the lower layers. These deficiencies are exhibited in the typical format of multilayer cell wherein the cell area is very small due to high cost and solar concentration is required to run the system at high heat in order to maximize the solar to electrical output. This high heat input increases the system complexity because it requires a large heat dissipation means to keep the multilayer solar cells from thermal degradation. In our invention the system is simplified in that it utilizes almost one hundred percent of the solar spectrum and broadband photons have an extremely high solar photon to heat conversion efficiency with insignificant loss as is well known to those skilled in the art.

An additional drawback in the multilayer design is that the solar concentration for multilayer solar cells has to be very uniform across the surface of the chip to achieve optimum efficiency. This necessitates very accurate formation and mounting of the solar trough or circular solar parabola or Fresnel lens approach to concentrating the solar energy.

In our invention we are only collecting heat into a black body and therefore the solar radiation can impinge the black body from any angle or direction and the necessity for uniform intensity is minimized. Solar heat collection may be by solar trough or circular solar parabola or any other solar radiation concentration means that allow the solar radiation to impinge onto the black body. The black body dissipates the solar heat sufficiently uniformly to allow our thermal-to-electricity devices to function optimally. Unlike the concentrated solar PV cell that requires dense lens to focus solar radiation onto the numerous solar cells for magnified cell output, the Hoda concentrator requires only a cheap parabola surface to collect reflected solar radiation. A single parabola surface is much cheaper than a Fresnel lens.

An additional drawback to the multilayer solar cell design is that the multilayer architecture does not utilize the heat itself. It transfers the heat and has to cool the chip from its high heat level to keep the multilayer chip from degrading, and does not extract any of the heat by transforming it into electricity. Our invention utilizes thermal electric conversion and utilizes multi-stack architecture that reuses the black body induced heat at several levels, typically three thermally optimized levels. At each level approximately sixteen percent of the thermal heat energy is transformed into electrical energy and drawn off. The cumulative thermal to electric extraction of the three layers is approximately forty percent, thereby reducing considerably the heat which must be dissipated to the atmosphere. Additionally our invention utilizes heat retention means of types and designs well known to those skilled in the art, to channel all the thermal energy through our multi chip stack, reducing waste heat and insuring optimum efficiency.

An additional drawback to the multilayer solar cell design is the complication of subdividing or multiplexing the solar cell architecture such that the voltage and amperage of the produced current can be organized to produce a current optimized for the end use. In our invention the construction of the thermal electric core chips allows for optimal organization, through series and parallel arrangement of the thermal electric couples, for the chip and the multi-chip stack to produce electricity optimized for the end use. Our thermal electric chip output can be organized to provide voltage and amperage levels of electricity of standard power outputs which are well-known to those skilled in the art, without additional electronic conversion cost.

### BRIEF DESCRIPTION OF THE DRAWINGS

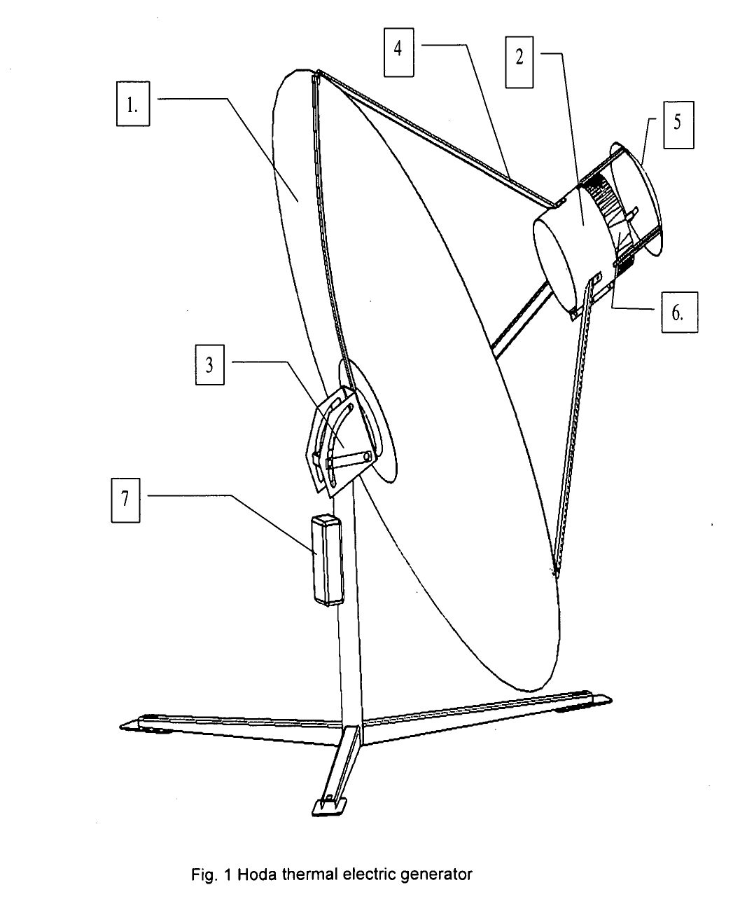

Referring to FIG. 1 is Hoda solar thermal electric generator

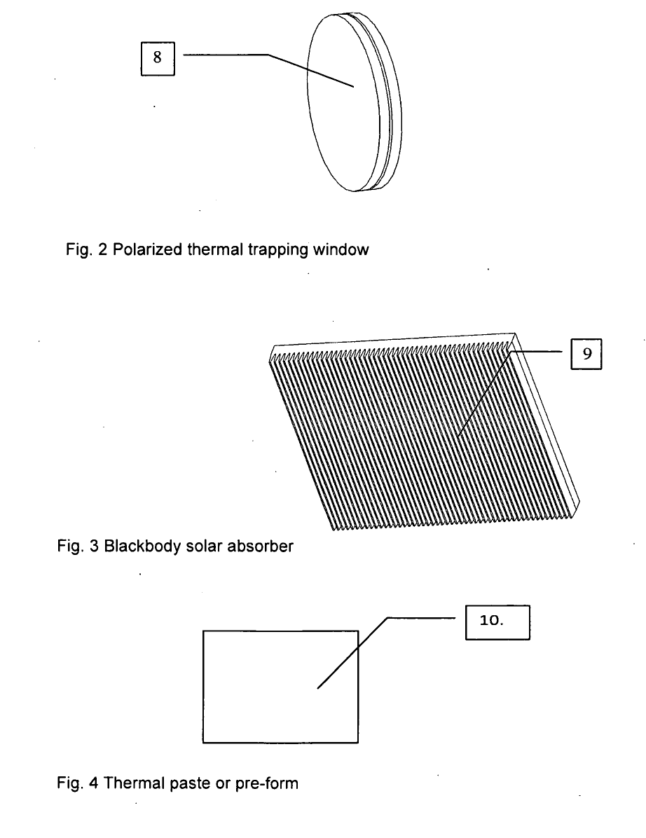

Referring to FIG. 2: said solar thermal energy is concentrated and passes through a thermal trapping window (8) composed of high temperature glass or quartz or other optically transparent materials well known to those skilled in the art.

Referring to FIG. 3: The concentrated solar energy impinges upon a blackbody absorber (9) mounted inside an interior housing and behind said thermal window (8).

Referring to FIG. 4 is Thermal adhesive

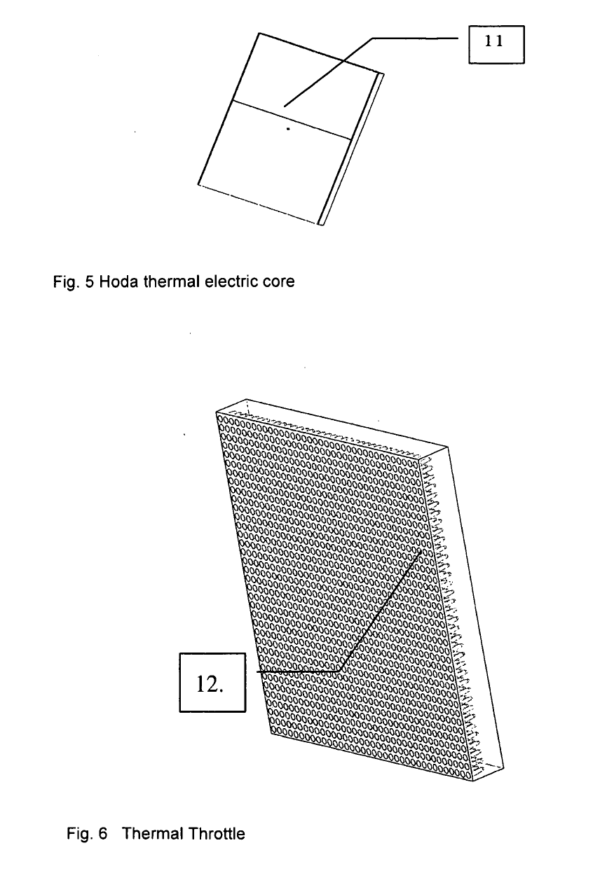

Referring to FIG. 5 is Hoda thermal electric core

Referring to FIG. 6 is Thermal throttle

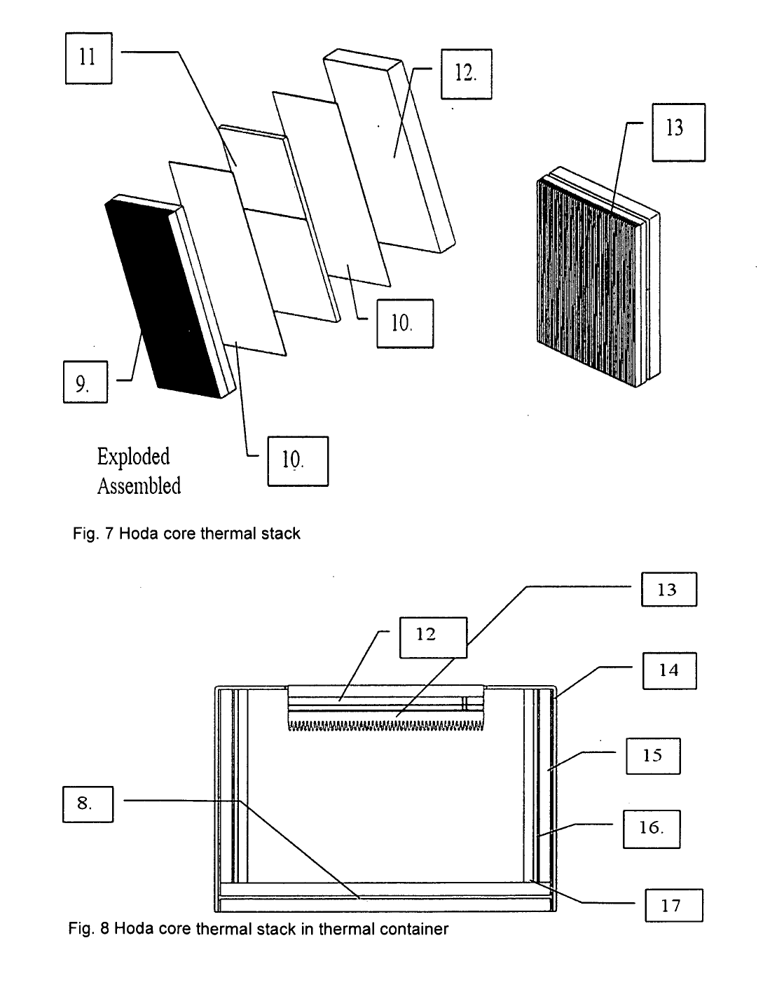

Referring to FIG. 7: Hoda core stack shows the exploded view spatial relationship of said black body absorber (9), said thermal adhesive layers (10), said Hoda thermal electric core (11) and said Thermal Throttle (12)

Referring to FIG. 8 is Hoda core thermal stack

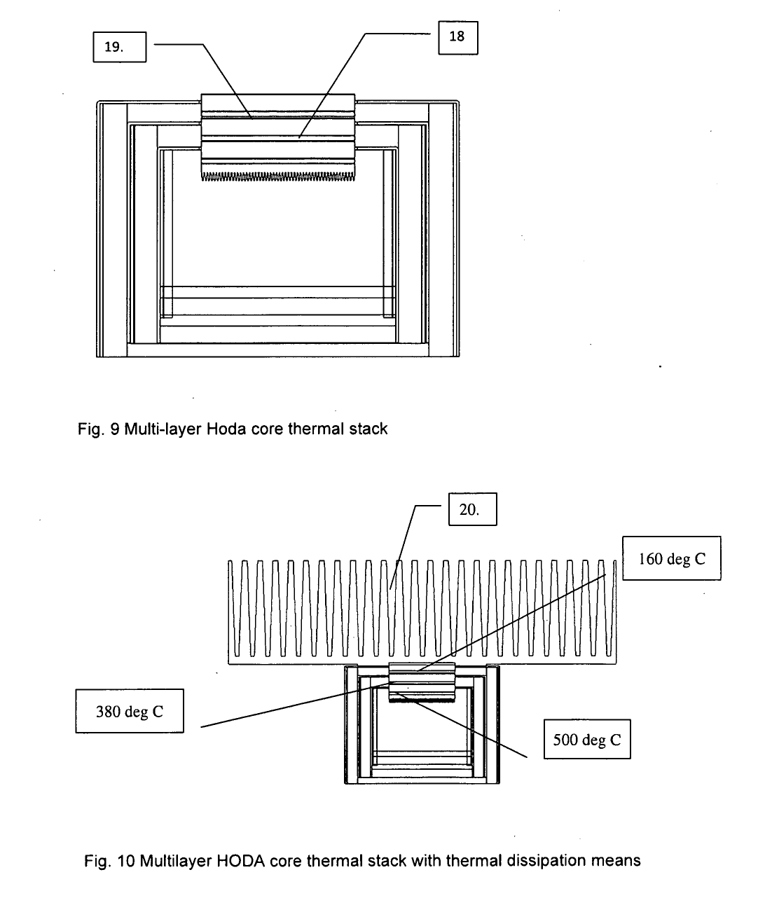

Referring to FIG. 9 is Multi-layer Hoda core stack

Referring to FIG. 10 is Multi-layer Hoda core thermal stack with thermal dissipation means

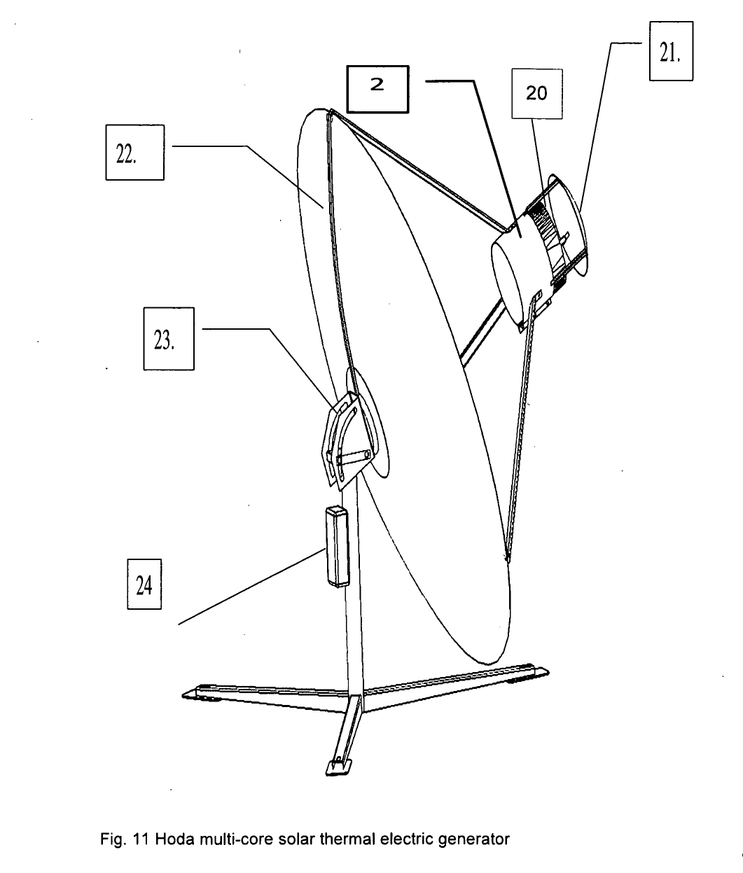

Referring to FIG. 11 is Hoda thermal electric generator

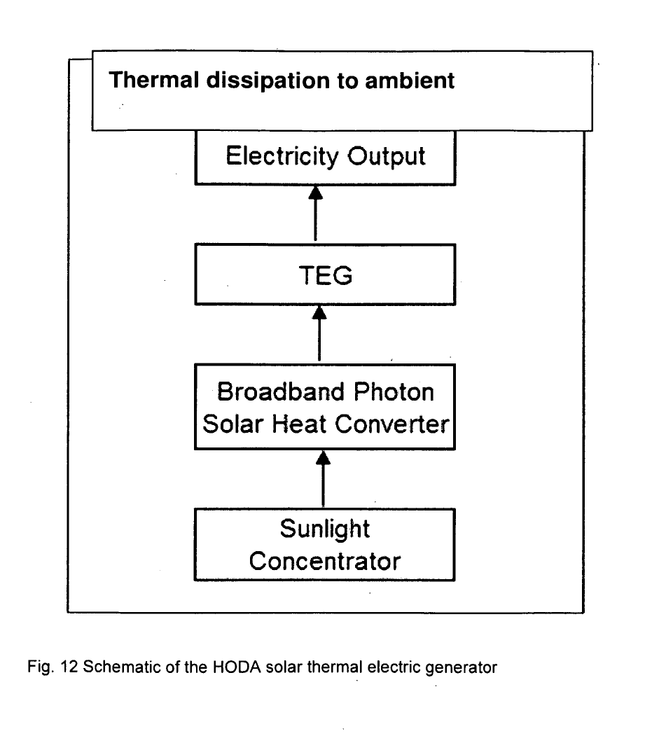

Referring to FIG. 12 is Schematics of the solar thermal electric generator

### DETAILED DISCUSSION

A solar electric generator is discussed which utilizes the natural energy of sunlight and converts it directly into DC electricity by means of a solid state thermal electric generator (TEG) at high efficiency. The said sunlight to electricity conversion requires neither Turbine/Stirling engine nor fluid/steam. The solar electric generator converts sunlight into electricity in two steps: 1) sunlight energy is converted into heat in a lower chamber that contains a broadband photon trapper known as the blackbody; 2) the heat is converted into electricity through the TEG in an upper chamber illustrated at below. The thermal electric conversion component is packaged from thermally cascading stack of multiple TEG cores. Each of the cores is composed of materials optimized to exhibit the thermal electric effect at progressively lower temperatures. The heat flow is optimized so that the heat is insulated with minimal energy loss all around except by flowing through the multi-cores stack architecture. The cores are produced through the chip fabrication or the semiconductor process that includes pn-couples or devices, large-scale integration circuitry, heat barrier, and substrates. The temperature differentiation across each core is optimized for the highest TEG efficiency as a function of the given materials. Referring to FIG. 1: Hoda solar thermal electric generator.

The solar collecting device (1), which may be of any form or material and which consists of forms well known to those skilled in the art, which efficiently reflects and focuses solar energy onto the solar trapping surfaces of the thermal generator head (2), is mounted on a base (3) which may be fixed or mobile to track optimum solar position and is of materials and forms well known to those skilled in the art. The solar thermal generator head (2) is mounted by a framework (4), composed of materials and forms well known to those skilled in the art, to position the solar thermal generator head (2) in the optimum position to focus the collected solar thermal energy directly on the solar trapping surfaces of said solar thermal generator head.

The device also has a thermal reflector-flow inducer (5) which reflects the direct solar rays from impinging on the heat sink (6) of said thermal generator head (2) and causes a thermally induced air flow to aid in extracting heat from said heat sink (6). Said solar electric generator also utilizes electrical cables and a power control box of types and designs well known to those skilled in the art (7) to convey said generated electricity to said box and convert said electricity to the appropriate DC or converted to AC format desired.

Thus, the power generating device of solar thermal electric generator has a highly efficient multi-core stacked architecture that efficiently converts sunlight to heat to electricity. The solar thermal electric generator is comprised of a mechanism to collect and reflectively concentrate direct solar photon energy. The solar energy is collected by a parabolic solar dish or other form of solar reflector and focused through thermal energy trapping windows onto a black body thermal collector. The thermal collector is integrated with an insulated thermal storage mass which retains sufficient heat to extend the electrical generation over interruptions in the solar incidence and for an extended time after said solar incidence has ceased. The solar thermal electric generator is also equipped with a mechanism to limit direct solar incidence onto said shaded back side of said Hoda multi-core device and an additional mechanism to track horizontally and vertically to optimize the incidence of the solar light for reflected concentration onto said Hoda multi-core generator.

Referring to FIG. 2, the solar light thermal trapping window, said solar thermal energy is concentrated and passes through a thermal trapping window (8) composed of high temperature glass or quartz or other optically transparent materials well known to those skilled in the art and of any convenient shape. Said thermal window (8) may also be coated with thermally transmissive and reflective coatings to reduce reflectance of the incoming sunlight and minimize back transmission of the thermal energy trapped by said thermal window. Said thermal window may also be constructed of two pieces polarized such that rotational misalignment will optimize or minimize the transmission of said thermal window (8).

Referring to FIG. 3: Heat Absorber

The concentrated solar energy impinges upon a blackbody absorber (9) mounted inside an interior housing and behind said thermal window (8). Said blackbody absorber (9) is constructed of material which is or can be coated black and is texture formed on its absorbing surface such that it optimally adsorbs said thermal energy and is of material types and designs well known to those skilled in the art such as anodized aluminum or aluminum nitride.

Referring to FIG. 4: Thermal Adhesive

In order to transmit said thermal energy efficiently from said blackbody (9) to the Hoda core (11) there is required an intermediate layer of thermal transfer adhesive (10), which can be of paste or pre-calendared form and composed of materials and by methods well known to those skilled in the art.

Referring to FIG. 5: Hoda Thermal Electric Core

The thermal energy from said black body absorber (9) is transferred by thermal adhesive (10) into the Hoda thermal electric core (11). Said Hoda core is composed of a high number matrix of thermal electric junctions configured at the end of wires of relative diameter to length of ten-to-one to twenty-to-one. These configurations accumulate the voltage and amperage generated by the individual junctions into desired levels of voltage and amperage. The transmission of said solar generated heat from the bimetallic junction side of said Hoda thermoelectric core to the interconnection side converts a percentage of said solar generated heat into electricity. The optimum for currently available thermal-electric materials is up to sixteen to twenty percent thermal electric conversion efficiency.

Referring to FIG. 6: Thermal Throttle

Thermally connected to the back side of said Hoda thermal electric core (11, 12, 13) by a second layer of said thermal adhesive (10) is the Thermal throttle (12). Said Thermal throttle (12) is composed of materials and formed in geometry such that it can regulate said thermal energy flow from the back side of said Hoda thermal electric core (11, 12, 13) in a manner which maintains a relatively constant thermal flow from the thermal electric junction side of said Hoda thermal electric core to the series and parallel connection side of said Hoda thermal electric core, thus maintaining a relatively constant thermal electric generation from said Hoda thermal electric core.

Referring to FIG. 7: Hoda Core Stack

FIG. 7 shows the exploded view spatial relationship of said black body absorber (9), said thermal adhesive layers (10), said Hoda thermal electric core (11) and said Thermal Throttle (12). Once adhered together into a optimally thermally transmissive unit the assembly is known as a Hoda core thermal stack (13).

The thermal energy from said black body absorber (9) is transferred by thermal adhesive (10) into the Hoda thermal electric core (11). Said Hoda core is composed of a high number matrix of thermal electric junctions. Said junctions are composed of two dissimilar materials which have the property of generating either free electrons or holes and when said junction is heated causes a flow of said electrons and holes along said wires. Said junctions are arranged in series and parallel configurations to accumulate the voltage and amperage generated by the individual junctions into desired levels of voltage and amperage. The transmission of said solar generated heat from the bimetallic junction side of said Hoda thermal electric core to the interconnection side converts a percentage of said solar generated heat into electricity. The optimum for currently available thermal electric materials is up to sixteen or twenty percent thermal to electric conversion efficiency. Said thermal electric cores are composed of materials which are optimized for thermoelectric conversion efficiency at different temperatures. PN junctions that exhibit said thermal electric generation are optimally composed of the material couples. Thus, the multi-cores stack architecture is capable of thermal and temperature management in order to optimize efficiency by operating thermal electric materials at the highest thermal electric efficiency well-known to those skilled in the art. Said stack of thermal electric conversion devices is composed of individual cores that composed of materials pairs which are optimized for highest thermal electric efficiency in the following temperature ranges. Said material pairs include but not limited to ones at below:

### 900 deg C. P=SiGe

### 900 deg C. N=SiGe

### 600 deg C. P=SnTe or CeFe4Sb12

### 600 deg C. N=CoSb3

### 500 deg C. P=PbTe or TAGS or (Bix, Sbi-x) Te3

500 deg C. N=PbTe (500 and below)

### 380 deg C. P=Zn4Sb3

380 deg C. N=PbTe (500 and below)

### 160 deg C. P=Bi2Te3

### 160 deg C. N=Bi2Te3

In the full implementation all five thermal electric couples are employed in HODA cores optimized for the maximum efficiency to function at their optimum temperature in a multi-core temperature cascade. In the preferred embodiment of said solar thermal electric generator (FIG. 1) three thermal electric couples are utilized at 500 [18], 380 [19], and 160 [20] degrees C (Reference FIG. 9). The thermal electric devices composed of said materials are separated by thermal throttles which maintain a uniform thermal flow such that said thermal electric device materials are maintained close to their optimum efficiency temperature within a stack of said generator modules. Said thermal throttles are constructed such that the thermal energy heat flow maintains said chip bottom surfaces at the optimum efficiency temperature for the materials employed. The cores are optimized by each core being created from pairs optimized for the thermal electric generation in specific temperature ranges, where the multi-cores stacked architecture contains the thermal electric materials pairs supported by the thermal barrier of proper insulating material(s) so that the heat flows through the said pairs only to generate the electricity.

Referring to FIG. 8: Hoda Core Thermal Stack in Thermal Container

The Hoda core thermal stack (13) is mounted by minimal attachment to a containment vessel (14), which is lined internally by a thermal isolation layer (15), such as fiber glass insulation or other heat insulation materials of types well known to those skilled in the art. Said thermal isolation layer (15) is lined internally with thermally reflective layers (16) composed of metal such as aluminum or other materials well know to those skilled in the art and lined internally in turn by a thermal heat retention layer (17), composed of ceramic or sodium or other material well known to those skilled in the art. The surrounding mass of said heat retention layer (17) absorbs heat given off by said Hoda core stack (FIG. 7). Said thermally reflective layer (16) and said thermally isolation layer (15) act to contain said thermal energy within said heat retention layer. This formation contains said thermal energy around said Hoda core thermal stack (13) allowing said thermal energy to escape only by migrating through said Hoda core thermal stack (13) and exiting through said thermal throttle (12). Said solar thermal energy is initially trapped inside said Hoda core thermal stack by single or multiple polarized or unpolarized thermal trapping windows (8).

The containment vessel (14) is attached to said heat sink and said polarized thermal trapping window (8) is mounted in said containment vessel (14).

Referring to FIG. 9: Multi Layer Hoda Core Stack

Additional Hoda core thermal stacks (Ref. FIG. 8), built of thermoelectric materials optimized for lower temperatures (18), (19) are contained in additional, larger size containment vessels which utilize said solar thermal energy which passes through said first Hoda core stack (FIG. 7) and forces said solar thermal energy to in turn pass through said lower temperature optimized Hoda core stacks (18), (19). The same solar thermal energy is thus utilized to generate electricity thermal electrically in all three stacks simultaneously, each of said Hoda core thermal stacks converting an optimum of sixteen to twenty percent of said solar thermal energy to direct current electricity. The thermal electric production is cumulative and three layers producing sixteen percent cascading thermal electric conversion sums to overall forty percent thermal to electric conversion.

Referring to FIG. 10: Multi-Layer Hoda Core Thermal Stack with Thermal Dissipation Means

The non-concentrated solar side of said multiple Hoda core triple stack is thermally connected to a heat dissipation means (20) which may be radiative, convective, thermal fluid flow or other means of heat dissipation well known to those skilled in the art. Said heat dissipative means maintains a maximum of temperature differential between said solar energy side and said heat dissipation side of said multiple Hoda core triple stacks.

Referring to FIGS. 9 and 10, the Hoda power generating device has scalable output architecture that contains multiple Cores assembled in a stacked arrangement. Each core has a heat receiving surface and a relatively cooler heat delivery surface. The heat receiving surface of the first of the stacked cores is exposed to an elevated temperature heat source and the heat delivery surface of the upper most of the stacked cores is exposed to a relatively cooler temperature such that each of the stacked cores is exposed to a temperature differential with the heat delivery surface of each core transmitting heat to the heat receiving surface of the adjacent core stacked thereon.

This arrangement forces said thermal energy collected by said black body solar energy absorber (9) to first activate said first layer chip at 500 degrees C. The thermal energy flows through said first layer chip and through said thermal throttle (14) inducing said thermal electric generation of sixteen to twenty percent of said thermal energy. The remaining thermal energy flows to said second layer chip at 380 degrees C. and the thermal electric generation of an additional sixteen to twenty percent is drawn off said reduced thermal energy. The remaining thermal energy flows through said third layer chip at 160 degrees C. and a third thermal electric generation draws off an additional sixteen to twenty percent of said reduced thermal energy. The remaining thermal energy flows through said heat sink (20) and is thermally dissipated into the surrounding environment. All three of said chip layers are connected in series to provide for a voltage accumulation in the range of one hundred Volts. In the preferred embodiment said three layers of chips provide ten Amps so that the cumulative power generated is one thousand watts, (one kilowatt). In the preferred embodiment, said Hoda core has built-in scalable architecture in part due to the said multiple Hoda core triple stacks.

Referring to FIG. 11: Hoda Thermal Electric Generator

The heat sink is mounted into said head housing (2) such that air can flow around said core stack housing and through said heat sink (20) cooling the exit side of said third core chip stack. The thermal reflector-flow inducer (21) causes a constant flow of air reducing said thermal energy flow back to ambient. The improvements in the state of the art of solar thermal electrical generation provided by this invention are inherent in the improved efficiency of thermal to electrical conversion of said solid state Hoda generator core and the optimized materials and form to make utilization of said Hoda solar thermal electric generator functional, cost effective and convenient.

The direct current electricity flow generated by said Hoda generator exits through electrical connections (22) of materials and types well known to those skilled in the art. Said connections and wires are routed through protective structural enclosures (23) to provide mechanical and environmental protection. Said electricity is processed in a electrical control box (24) which provides for connective use of said electricity as direct current of any amperage and voltage desired or can convert said direct current to alternating current, by electric and electronic means well known to those skilled in the art, into amperages and voltages in common usage within the existing electrical systems around the world. Thus, the Hoda power generating device contains thermal conversion devices that have varied design appropriate by way of both heat energy sources and configurations. The configuration includes but not limited to thermal energy collection, devices geometry, and multi-stack numbers in total that is deemed efficient architecture well-known to those skilled in the art. The Hoda power generating device effectively reuses and reduces the heat loss from the thermal collector side that maximally generates electricity by a mechanism of managing thermal side and non-thermal side. The opposite/non-thermal side of said Hoda multi-core generator is connected to a thermal dissipation mechanism which maintains a high thermal differential between the concentrated thermal side and the non-thermal back side. The thermal energy collected within said thermal collector raises the temperature of the said thermal conversion devices with one or more Hoda core generator modules, causing them to generate a DC electric current. The electric current is organized by series and parallel into a useful high power DC electric current of and appropriate voltage and amperage for any use.

This invention of an efficient form of solid state solar thermal electric generator provides for a constant production of solar generated electricity. Said heat retention material (17) within said Hoda core thermal stack (FIG. 8) provides for electrical production continuity during short solar energy interruptions such as intermittent cloud cover and also provides for additional electrical production for a period of time after the solar incidence has declined or ceased.

Referring to FIG. 12: Schematics of the Solar Thermal Electric Generator

Said solar thermal energy carried in said broadband photons is reflected from said sunlight concentrator. Said broadband photons impinge on said solar heat converter (black body) and raise its temperature. Said photonic energy is converted into thermal energy. Said thermal energy heats said junctions of said thermal electric generator as said thermal energy flows through. Said electrical output is created by said thermal electric effect and finally said remaining thermal energy is dissipated to the ambient surroundings. The HODA solar thermal electric generator provides for solid state solar photonic to electric energy conversion without the requirement for any moving parts of intermediate materials.

We claim:

1. A power generating device of solar thermal electric generator has highly efficient multi-core stacked architecture that efficiently converts sunlight to heat to electricity: wherein a solar thermal electric generator comprised of a means to collect and reflectively concentrate direct solar photon energy, said solar energy is collected by a parabolic solar dish or other form of solar reflector and focused through thermal energy trapping windows onto a black body thermal collector, said thermal collector is integrated with an insulated thermal storage mass which retains sufficient heat to extend the electrical generation over interruptions in the solar incidence and for an extended time after said solar incidence has ceased, said solar thermal electric generator is also equipped with means to limit direct solar incidence onto said shaded back side of said Hoda multi-core device and additional means to track horizontally and vertically to optimize the incidence of the solar light for reflected concentration onto said Hoda multi-core generator.

2. Said device of claim one with said multi-cores stack architecture is capable of the thermal and temperature management in order to optimize efficiency by operating thermal electric materials at the highest thermal electric efficiency well-known to those skilled in the art. Said stack of thermal electric conversion devices is composed of individual cores that composed of materials pairs which are optimized for highest thermal electric efficiency in the following temperature ranges. Said material pairs include but not limited to ones at below:
900 deg C. P=SiGe
900 deg C. N=SiGe
600 deg C. P=SnTe or CeFe4Sb12
600 deg C. N=CoSb3
500 deg C. P=PbTe or TAGS or (Bix, Sbi-x) Te3
500 deg C. N=PbTe (500 and below)
380 deg C. P=Zn4Sb3
380 deg C. N=PbTe (500 and below)
160 deg C. P=Bi2Te3 160 deg C N=Bi2Te3
Said thermal electric devices composed of said materials are separated by thermal throttles which maintain a uniform thermal flow such that said thermal electric device materials are maintained close to their optimum efficiency temperature within a stack of said generator modules.

3. Said power generating device of claim one has scalable output architecture of Hoda generator that contains multiple Cores assembled in a stacked arrangement, wherein each core having a heat receiving surface and a relatively cooler heat delivery surface, the heat receiving surface of the first of the stacked cores being exposed to an elevated temperature heat source and the heat delivery surface of the upper most of the stacked cores being exposed to a relatively cooler temperature such that each of the stacked cores is exposed to a temperature differential with the heat delivery surface of each core transmitting heat to the heat receiving surface of the adjacent core stacked thereon.

4. The cores of claim two are optimized wherein each core is created from pairs optimized for the thermal electric generation in specific temperature ranges: wherein the multi-cores stacked architecture contains the thermal electric materials pairs supported by the thermal barrier of proper insulating material(s) so that the heat flows through the said pairs only to generate the electricity.

5. Said device of claim one contains thermal conversion devices have varied design appropriate by way of both heat energy sources and configurations: wherein the configuration includes but not limited to thermal energy collection, devices geometry, and multi-stack numbers in total that is deemed efficient architecture well-known to those skilled in the art, Said device of claim one effectively reuses and reduces the heat loss from the thermal collector side that maximally generates electricity by means of managing thermal side and non-thermal side. The opposite/non-thermal side of said Hoda multi-core generator is connected to a thermal dissipation means which maintains a high thermal differential between the concentrated thermal side and the non-thermal back side. The thermal energy collected within said thermal collector raises the temperature of the said thermal conversion devices with one or more Hoda core generator modules, causing them to generate a DC electric current. Said electric current is organized by series and parallel into a useful high power DC electric current of and appropriate voltage and amperage for any use.
